(19) United States
(12) Patent Application Publication
(10) Pub. No.: US 2006/0193477 A1
(43) Pub. Date: Aug. 31, 2006

(54) System for audio signal processing with sound spectrum selection

(76) Inventors: Guido Zehnle, Gaggerjau (DE); Ludwig Gunther, Muggensturm (DE)

Correspondence Address: THE ECLIPSE GROUP, 10605 BALBOA BLVD., SUITE 300, GRANADA HILLS, CA, 91344, US

(21) Appl. No.: 11/314,075

(22) Filed: Dec. 20, 2005

Related U.S. Application Data
(63) Continuation-in-part of application No. PCT/EP04/06142, filed on Jun. 7, 2004.

(30) Foreign Application Priority Data
Jun. 20, 2003 (EP) 03013421.7

(51) Int. Cl. H03G 3/00; H04B 15/00

(52) U.S. Cl. 381/61; 381/94.2

(57) ABSTRACT

An audio signal processing system where an input audio signal is processed with a suitable sound spectrum to form an audio output signal for outputting via a loudspeaker or other means. The audio signal processing system may include a sound spectrum selection module capable of automatically selecting a sound spectrum from a plurality of different sound spectra suitable for processing the input audio signal and changing that sound spectrum whenever there is a change in the source of the input audio signal.

### CROSS-REFERENCE TO RELATED APPLICATIONS

This application is a continuation-in-part of and claims priority of International Patent Application Serial No. PCT/EP2004/006142, filed Jun. 7, 2004, titled AUDIO SIGNAL PROCESSING DEVICE AND AUDIO SIGNAL PROCESSING METHOD WITH SOUND SPECTRUM SELECTION, which claims priority to European Patent Application Serial No. 03013421.7 filed Jun. 20, 2003, the entirety of both applications are incorporated by reference into this application.

### BACKGROUND OF THE INVENTION

1. Field of the Invention

The invention relates to an audio signal processing system that selects a sound spectrum for processing an audio signal, and a method for selecting a sound spectrum for processing an audio signal.

2. Related Art

It is appreciated by those skilled in the art that it is possible to process an audio signal in accordance with a predetermined sound spectrum before its reproduction using amplifiers and loudspeakers. Listening to classical music, for example, which generally has a high dynamic range, may not be as enjoyable in a moving motor vehicle because of road noise. To enable the quieter passages of the music to be heard, the volume of the audio system may have to be increased. Conversely, the volume of louder passages of the acoustic warning signals within the vehicle's environment. In order to avoid frequent adjustment of the volume of an audio system, a compressor in conjunction with a limiter is normally used.

In the case of changes between different types of programs being played on the audio system, however, it may be desirable to adjust the settings of the compressor and limiter according to the type of program being played. In a moving motor vehicle, these required adjustments may distract the driver's attention to road traffic, which is obviously a disadvantage in a motor vehicle audio system. Manual adjustments of this type after selection of a different program are particularly critical in cases where it is not possible to select sound spectra that have already been stored simply by key actuation, and individual sound spectrum parameters have to be separately adjusted.

There are many broadcasting systems where the audio signals are transmitted together with data signals in order to improve the functionality of the broadcasting system. As an example, the Radio Data System (RDS) was developed within the European Broadcasting Union to provide a means by which digital information is transmitted in FM broadcasting. By means of this digital information, the name of the transmitter and its transmission frequency may be displayed to the user on a display device. When used in motor vehicles, the radio data system also enables continuous automatic changeover to whichever transmission frequency of the selected program is most favorable on the reception side. A similar system is in use in the United States, the Radio Broadcast Data System (RBDS), which covers AM broadcasting also.

In these systems, radio programming is generally identified by a program type (PTY) code that is transmitted in addition to the audio signal. The PTY code distinguishes between, for example, news, information, talk, and classical music programming. By means of this code, it is also possible to carry out a controlled transmitter search according to program types so that a vehicle driver can select the desired type of programming controllably from a number of available transmitters.

Another example is a data radio channel with the designation SWIFT/DARC (DAta Radio Channel) capable of transmitting additional information via an FM radio channel. Binary information sent at a data rate of 10 kilobits/sec via a radio transmitter can be decoded in the receiver by means of a suitable terminal, a combination of FM radio and data decoder. This system is used for the transmission, for example, of detailed traffic reports and news in Japan, where the RDS is not used.

Another digital technology whose use is becoming more widespread is Digital Audio Broadcasting (DAB), which has the ability to deliver CD-quality stereo sound robustly and reliably using only a rod antenna. In moving vehicles in particular, FM reception is often distorted or interrupted by multipath interference, sometimes refereed to as “echoes” or “shadows,” as reflections from hills and buildings arrive out of phase with the main signal. In contrast, a DAB receiver uses these “shadows” to reinforce the main signal and thus is well suited for car radios. DAB may also carry text and images as well as sound, and all DAB receivers may be equipped to handle non-audio data. This allows the display of at least two 16-character lines of text, allowing program selection by name or program type, and the display of program-associated data (PAD), such as album title, song lyrics, or contact details.

Moreover, although an audio signal may be described as a signal capable of being amplified and played through a loudspeaker as music, it may also include speech signals that are processed in a similar manner, such as, for example, speech signals from purely news transmitters or from mobile radio units.

In addition to the multiplicity of different possible input audio signal sources, there is also a multiplicity of data signals that may be transmitted with audio signals and that may be used for allocation of a sound spectrum. This additional information in these data signals need not be additional information that is linked directly with a program type or a program code. The additional information may be in the form of a program type (PTY) code, a program code according, for example, to the RDS or the RBDS, additional information in accordance with SWIFT/DARC or DAB, or purely accompanying information such as, for example, text information on a DVD (Digital Versatile Disc) or CD (Compact Disc).

In addition to data that is more or less directly connected with the input audio signal, the additional information used may also be additional information obtained by the audio signal processing system itself. This includes, for example, a speech input signal received by a microphone and evaluated by speech recognition software. Additionally, the additional information may also be the information concerning a specific signal input channel of the system, when a special audio signal source, for example, a mobile radio unit, is connected with this signal input.

Thus, there is a need for an audio system that is able to automatically process a plurality of different input audio signals with a suitable sound spectrum without user intervention so that, in particular, for motor vehicle drivers, the user is not required to make the required adjustments himself.

### SUMMARY OF THE INVENTION

An audio signal processing system where an input audio signal is processed with a suitable sound spectrum to form an audio output signal for outputting via a loudspeaker or other means is disclosed. The output of the audio signal processing system may also include text information that is displayed to the system's user. The audio signal processing system may also include a sound spectrum selection module capable of automatically determining a suitable sound spectrum from a plurality of different sound spectra whenever there is a change in the source of the input audio signal. The audio signal processing system may also include an audio signal processing module that processes an audio input signal with the selected sound spectrum, as well as memory for storing sound spectra in an allocation table.

Additionally, a method of processing an input audio signal with a suitable sound spectrum sₙ selected from a plurality of different sound spectra that may be stored in memory is disclosed. The method may include obtaining the information necessary to select the appropriate sound spectrum from the input audio signal itself, from a data signal transmitted with a corresponding input audio signal, or from an analysis of the input audio signal, dependent on the source of the input audio signal.

Reference is made to the term “module,” which may refer to an element or unit of either software or hardware that may perform one or more functions or procedures. With respect to software, a module may be part of a program, which may be composed of one or more modules that are independently developed and linked together when the program is executed. With respect to hardware, the module may be any self-contained hardware component or a hardware component that comprises two or more hardware or software components.

Other systems, methods and features of the invention will be or will become apparent to one with skill in the art upon examination of the following detailed description. It is intended that all such additional systems, methods, features and advantages be included within this description, be within the scope of the invention, and be protected by the accompanying claims.

### BRIEF DESCRIPTION OF THE DRAWINGS

The invention can be better understood with reference to the following figures. The components in the figures are not necessarily to scale, emphasis instead being placed upon illustrating the principles of the invention. In the figures, like reference numerals designate corresponding parts throughout the different views.

FIG. 1 shows a block diagram of an example of an implementation of a system that processes an audio signal responsive to a selected sound spectrum.

FIG. 2 shows a flow diagram of an example of a sequence for audio signal processing responsive to a selected sound spectrum.

### DETAILED DESCRIPTION

In the following description of one example of one implementation, reference is made to the accompanying drawings, and which show, by way of illustration, one implementation in which the invention may be practiced. Other implementations may be utilized and structural changes may be made without departing from the scope of the present invention.

An audio signal processing system consists generally of a multiplicity of individual components that are connected with other components. In this disclosure, only the specific devices and method steps necessary to an understanding of the special arrangement and functions of the disclosed audio signal processing system and method are described, and it is appreciated that the disclosed audio signal processing system and method may be used in many systems and implementations. In the described implementation, the audio signal processing system is shown as part of a motor vehicle audio system for operation in a motor vehicle.

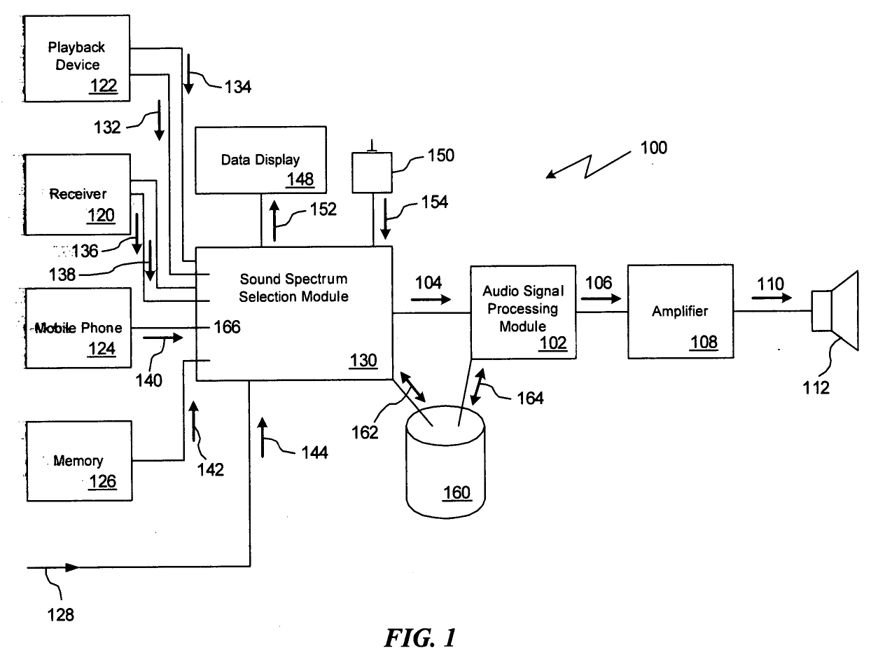

In FIG. 1, a block diagram of an example of an implementation of a system that processes an audio signal responsive to a selected sound spectrum is shown. The audio signal processing system 100 may include an audio signal processing module 102, in which an input audio signal audioᵢₙ 104 is processed in accordance with the requirements of a selected sound spectrum. The audio signal audioₒᵤₜ 106 thus processed with the sound spectrum sₙ may be output to other devices such as, for example, an amplifier 108, which produces an amplified signal 110 that is input to a loudspeaker 112.

The input audio signal audioᵢₙ 104 originates from an audio signal source that may be, for example, a receiver 120 for receiving a radio signal, e.g., an FM-AM tuner, or a CD or DVD playback device 122. Another audio signal source may be a mobile phone unit 124, such as a Global System for Mobile Communications (GSM) unit that outputs a received signal 140, i.e., a speech signal, as the source of input audio signal audioᵢₙ 104. Other examples of audio signal sources may include a microphone 128 that receives speech signals from the user and forwards these signals 142, which may be control instructions, as the source of input audio signal audioᵢₙ 104. Another example audio signal source may be a memory 126 in which segments of music or speech signals previously selected by the user of the system have been stored for future use as input audio signals.

These input audio signals may be transmitted via appropriate connections to a sound spectrum selection module 130 and then transmitted by the sound spectrum selection module 130 to the audio signal processing module 102. The audio signal processing module 102 may perform the functions, for example, of an equalizer. In the embodiment illustrated, the several audio signal sources receiver 120, playback device 122, mobile phone 124, memory 126, and microphone 128 are in signal communication with the sound spectrum selection module 130. However, other implementations that have just a single audio signal source are possible, for example, the receiver 120, for reception of a radio signal as an input audio signal.

The sound spectrum selection module 130 may be in signal communication with memory device 130, in which there may be stored a plurality of m different sound spectra sₙ, numbered 0, 1, 2, . . . m−1. The different sound spectra sₙ may be a fixed number of preset sound spectra. However, the memory device 130 may also be configured so that the individual parameters of the sound spectra sₙ may be changed by a user by inputting other sound spectra or by modifying the preset sound spectra depending on the configuration of the audio signal processing module 102.

For each input audio signal received for onward transmission, the sound spectrum selection module 130 selects a suitable sound spectrum, i.e., the best suited sound spectrum for that input audio signal out of the plurality of different sound spectra sₙ. By the sound spectrum selection module 130 instructing the memory 160 by means of a selection signal 162 that is clearly allocated to one of the different sound spectra in the memory 126, the memory 160 then outputs the associated sound spectrum sₙ via spectrum signal 164 to the audio signal processing module 102, which then processes the input audio signal with the selected sound spectrum sₙ.

A central control device (not shown) connected to the individual system components may be used to control the individual sequences, but it is also possible to use other implementations with structurally independently-controlled system components or embodiments in which all or most of the system components are incorporated in a single integrated circuit. In order that the sound spectrum selection module 130 may receive a criterion for selection of the suitable sound spectrum sₙ from the plurality m of different sound spectra, additional information may be processed in the sound spectrum selection module 130.

In the case of a receiver 120 for reception of a radio signal, the additional information may be found in an additionally transmitted data signal 138 that is distinctly identified with the type of radio program being transmitted. For example, the additional information may be a program type (PTY) code that is transmitted together with the input audio signal 136 or parallel thereto by a radio transmitter and received at the receiver 120. From analysis of the PTY code, the sound spectrum selection module 130 is able, for example, to distinguish between a radio program that transmits news, light music, or classical music. The sound spectrum selection module 130 then selects a sound spectrum sₙ=s₀, s₁ or s₂, said sound spectra s₀, s₁ or s₂ being adapted accordingly to the reproduction of news, light music, or classical music, respectively. Thus the received input audio signal 136 is optimized in the audio signal processing module 102 for the playback of news, light music, or classical music, as the case may be, and output as audio output signal 106.

Instead of or in addition to the PTY code, the additional information may also be in the form of the additional information available in the RDS/RBDS. In that case, the individual sound spectra sₙ related to the codes of the digital information transmitted by the RDS or RBDS may be stored in memory 160. The additional information may, for example, be the name of a specific transmitter and/or its transmission frequency stored in memory 160. In that case, it may be desirable for the user of the audio signal processing device, i.e., the motor vehicle driver, to have a processing facility, such as a completion facility, so that he can subsequently allocate specific transmitters and/or frequencies to a selected sound spectrum. In addition or alternatively, it is also possible to transmit with the RDS/RBDS additional information directly to the sound spectrum selection module 130 for processing.

For radio units such as receiver 120, it is also possible to use the additional information that is transmitted via an FM radio channel in accordance with the requirements of the SWIFT or DARC radio systems as well as the DAB radio system. If the receiver 120 does not break down the received radio signal into an input audio signal and a separate data signal, this may be carried out by a corresponding system component in the sound spectrum selection module 130.

In another implementation, another component that splits a received signal into an input audio signal and a data signal with additional information may be used to transmit these signals to the sound spectrum selection module 130. If a separate input audio signal and a data signal separate therefrom have already been prepared on the input side, the input audio signal may be transmitted directly to the audio signal processing module 102, bypassing the sound spectrum selection module 130, while the separate data signal is transmitted to the sound spectrum selection module 130 for selection of the suitable sound spectrum.

Thus, in this manner, the sound spectrum selection module 130 may also receive signals from many other signal sources. Particularly in the case of a motor vehicle radio, there are many diverse sources of audio input signals that will benefit from being connected to the sound spectrum selection module 130, which then selects the suitable sound spectrum sₙ for the corresponding audio output signal.

In the case of the playback device 122, the data signal 134 may be used, for example, as a source of text information that may be stored in memory together with the actual audio signal. This additional information may in turn be used for the selection of a sound spectrum, but may also be any other additional information that the sound spectrum selection module 130 may use to find a suitable sound spectrum by, for example, using an allocation table appropriately mapping sound spectrum to audio input signals.

In contrast to the examples described above, the audio signal processing system 100 may also select a suitable sound spectrum sₙ for an input audio signal that is not accompanied by a corresponding data signal. The mobile phone 124 is an example of an audio signal source of this type. With this audio signal source, speech data may be transmitted as, for example, input audio signal 140 to the sound spectrum selection module 130 or to the audio signal processing module 102. Because input audio signal 140 is primarily a speech signal, a sound spectrum sₙ optimized for this type of input audio signal may be stored in memory 160 and may also take into account not only speech as the input audio signal but also a particularly poor and noisy audio signal quality having radio communication interference; that is, there may be a second sound spectrum sₙ₊₁ in memory 160 allocated to input audio signals 140 that are weaker than a predetermined level. As a criterion for the sound spectrum selection module 130 to select sound spectrum sₙ or sₙ₊₁ in memory 160, the audio signal processing system 100 may use, for example, input channel 166. That is, the special sound spectrum sₙ is always used in the processing of the input audio signal 140 when the audio signal processing module 102 receives the signal from input channel 166 to which the mobile phone 124 is connected.

The audio signal processing system 100 may also select a suitable sound spectrum sₙ by means of direct analysis of the input audio signal introduced into the sound spectrum selection module 130. For example, the frequency response and/or the dynamic curve of the input audio signal may be analyzed in the sound spectrum selection module 130. In the case of classical music, for example, the distinguishing criterion may be in the form of a very large frequency spectrum with highly varying dynamic intensities. For lighter music, the criterion may be the incidence of uniformly rhythmic and/or less intensively varying frequency and dynamic values. Speech signals and news transmitters may, for example, be defined and recognized by reference to the typically very restricted frequency contents of the input audio signals.

The sound spectrum selection module 130 may also be in signal communication with a data display 148 that receives the additional information from a data signal or from prepared information corresponding to the input audio signal for display to the user, for example, the motor vehicle driver. Where PTY, RDS, or RBDS codes are used, the corresponding displays may be directly displayed without further processing. The audio signal processing system 100 may also perform special processing prior to direct display of the selected sound spectrum.

Additionally, the audio signal processing system 100 may also include means for switching off the automatic selection of the suitable sound spectrum sₙ. This may be, for example, a simple key switch 150, from which an ON/OFF signal 154 is transmitted to the sound spectrum selection module 130 or a central control device (not shown). Depending on the state of signal 154, the operator may switch the automatic sound selection on or off. The audio signal processing system 100 may also be configured for direct selection of one of the available different sound spectra sₙ or manual adjustment by the user starting from a basic sound spectrum after the automatic sound spectrum selection has been switched off. For example, the user of a motor vehicle may wish to reproduce the full dynamic range of classical music when the motor vehicle is at rest and thus may switch the automatic sound selection off and then manually select the desired sound spectrum.

In addition to key switch 150, the audio signal processing system 100 may also include other inputting facilities that the user may use to influence sound spectrum selection. For example, microphone 128, in particular, a microphone in signal communication with the mobile phone 124, may be used in order to input speech commands as additional information. In this case, such speech commands may be analyzed and processed accordingly by the sound spectrum selection module 130 or some other system component such as, for example, a central control device (not shown).

Additional information may be allocated to a memory in which different sound spectra are stored. In addition to the installation of predetermined sound spectra, freely programmable sound spectra may also be installed so that a user may individually program in sound spectra mapped to special additional information selected by the user. The input device used, for example, may be a central control device (not shown) or other similar devices.

In order that a listener or user need not continually change the selection of the sound spectrum after a change of the type of program, a circuit arrangement as described above permits automatic selection of the suitable sound spectrum. For example, for recognition of the type of program associated with a radio signal, a program type (PTY) code that is made available by the program provider may be used. In the case of FM operation, this may, for example, be the RDS or RBDS data signal in which a PTY code is contained. Thus after evaluation of the RDS/RBDS signal, a radio receiver may identify the type of program and the sound adjustment may then be carried out after selection of the appropriate sound spectrum.

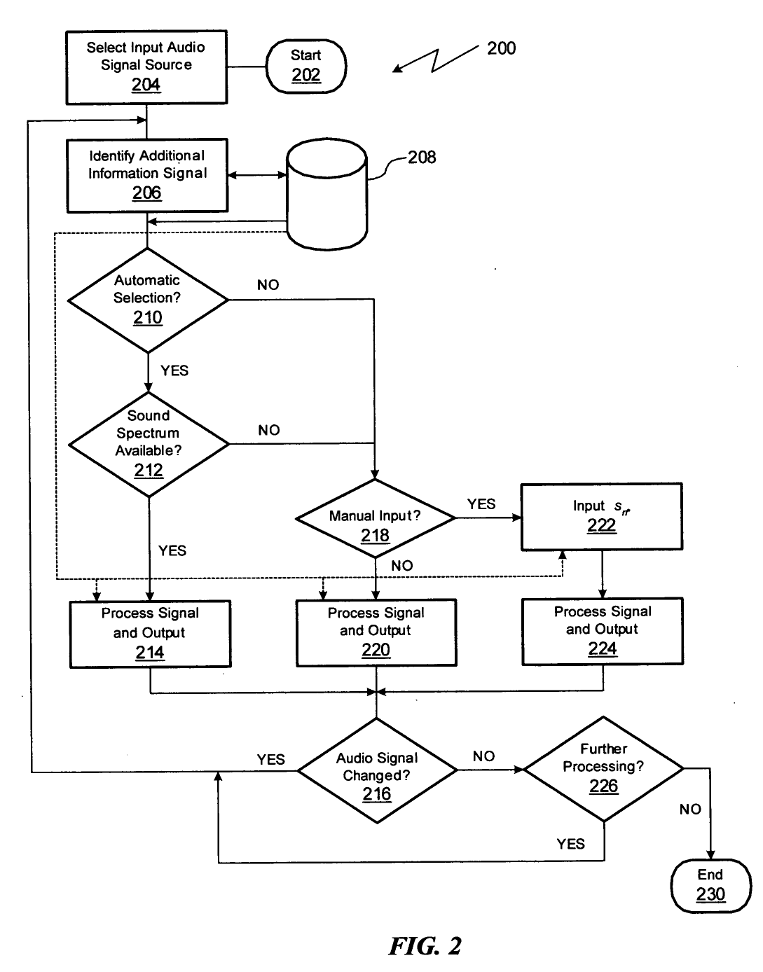

In FIG. 2, a flow diagram of an example sequence for audio signal processing responsive to a selected sound spectrum is shown. The process starts at step 202, which may include activating the audio signal processing system 100 of FIG. 1. In step 204, an input audio signal source is selected. This may be the selection of a different radio transmitter or band of receiver 120, FIG. 1, but may also be the selection of a different audio signal source, for example, playback device 122, mobile phone 124, microphone 128, or retrieval of selected audio signals from memory 126, FIG. 1. Additionally, an input audio signal audioᵢₙ may be automatically selected, as in the case of, for example, receiving traffic news via the receiver 120, FIG. 1, or a telephone call via the mobile phone 124, FIG. 1, which may be output by the loudspeaker 112.

After determination or selection of the input audio signal source, the most suitable or directly related additional information signal is identified in step 206. In step 208, the appropriate sound spectrum sₙ is then selected and transmitted to the audio signal processing module 102, FIG. 1, for processing with the appropriate audio input signal. In this particular implementation, there is a continuous determination as to whether the automatic selection of the sound spectrum is switched on.

Therefore, after selecting the appropriate sound spectrum sₙ, the process then proceeds to decision step 210 where the determination is made. If the automatic selection of the sound spectrum is ON, the process proceeds to decision step 212. In decision step 212, the system determines whether a suitable sound spectrum sₙ is available for processing the input audio signal. If a suitable sound spectrum sₙ is available, in step 214 the audio output signal is produced from the input audio signal and where applicable, the selected sound spectrum sₙ may be processed and there may be, for example, output to the data display 148, FIG. 1.

If, in decision step 210, it is found that automatic selection of the sound spectrum sₙ is not required, or if, in decision step 212, it is found that no suitable sound spectrum is available or no suitable additional information signal is available, then the additional information signal is ignored and the process proceeds to decision step 218. In decision step 218, if manual sound spectrum input is selected, then the process goes to step 222, where sound spectrum sₙ* is manually input by the user or a previously stored sound spectrum is modified by the user. From step 222, the process then goes to step 224, where the audio output signal is produced with sound spectrum sₙ*. If manual input is not selected, the process then goes from decision step 218 to step 220, where the audio output signal is produced with a standard sound spectrum sₙ_{⁰}.

After the audio output signal is processed in either of steps 214, 220, or 224, the process goes to decision step 216 where it is determined whether the input audio signal, for example, the reproduced radio program, or the audio signal source has changed. If it has, the process returns to step 206 to determine whether another additional information signal is available. If the audio input signal has not changed, the process goes to step 226 where it is determined if another input audio signal is to be processed. If there is, the process returns to step 216 to determine whether the input audio signal has changed. If not, e.g., the vehicle radio has been switched off, the process ends in step 230.

The processes described in FIGS. 1 and 2 may be performed by hardware or software. If the process is performed by software, the software may reside in software memory (not shown) in a controller, memory, or a removable memory medium. The software in memory may include an ordered listing of executable instructions for implementing logical functions (i.e., “logic” that may be implemented either in digital form such as digital circuitry or source code or in analog form such as analog circuitry or an analog source such an analog electrical, sound or video signal), may selectively be embodied in any computer-readable (or signal-bearing) medium for use by or in connection with an instruction execution system, apparatus, or device, such as a computer-based system, processor-containing system, or other system that may selectively fetch the instructions from the instruction execution system, apparatus, or device and execute the instructions. In the context of this document, a “computer-readable medium” and/or “signal-bearing medium” is any means that may contain, store, communicate, propagate, or transport the program for use by or in connection with the instruction execution system, apparatus, or device. The computer readable medium may selectively be, for example but not limited to, an electronic, magnetic, optical, electromagnetic, infrared, or semiconductor system, apparatus, device, or propagation medium. More specific examples, i.e., “a non-exhaustive list” of the computer-readable medium, would include the following: an electrical connection (electronic) having one or more wires, a portable computer diskette (magnetic), a RAM (electronic), a read-only memory “ROM” (electronic), an erasable programmable read-only memory (EPROM or Flash memory) (electronic), an optical fiber (optical), and a portable compact disc read-only memory “CDROM” (optical). Note that the computer-readable medium may even be paper or another suitable medium upon which the program is printed, as the program can be electronically captured, via for instance, optical scanning of the paper or other medium, then compiled, interpreted or otherwise processed in a suitable manner if necessary, and then stored in a computer memory.

It will be understood that the foregoing description of numerous implementations has been presented for purposes of illustration and description. It is not exhaustive and does not limit the claimed inventions to the precise forms disclosed. Modifications and variations are possible in light of the above description or may be acquired from practicing the invention. The claims and their equivalents define the scope of the invention.

What is claimed is:

1. An audio signal processing system, the system comprising:
an audio signal processing module for processing an input audio signal with a sound spectrum and outputting an audio output signal processed with the sound spectrum; and
a sound spectrum selection module capable of selecting the sound spectrum from a plurality of different sound spectra responsive to additional information that is associated with the input audio signal, where the additional information is available to the audio signal processing module together with or parallel to the input audio signal.

2. The audio signal processing system of claim 1, where at least one source of the input audio signal is selected from the group consisting of a receiver, a playback device, a mobile phone, a memory, and a microphone.

3. The audio signal processing system of claim 1, where the sound spectrum selection module is configured to automatically select the sound spectrum responsive to the additional information associated with the input audio signal.

4. The audio signal processing system of claim 3, where the additional information is contained in a data signal associated with the input audio signal.

5. The audio signal processing system of claim 4, where the data signal associated with the audio signal is transmitted independently of the input audio signal.

6. The audio signal processing system of claim 5, where the additional information contained in the data signal includes program codes or program type codes.

7. The audio signal processing system of claim 3, where the additional information is transmitted independently of the audio sound signal from the audio signal source.

8. The audio signal processing system of claim 3, where the additional information further includes identification of the channel by which the input audio signal is transmitted to the sound spectrum selection module.

9. The audio signal processing system of claim 1, where the sound spectrum selection module is configured to select the sound spectrum responsive to an audio analysis of the input audio signal.

10. The audio signal processing system of claim 9, where the audio analysis of the input audio signal includes a frequency or a dynamic analysis.

11. The audio signal processing system of claim 2, further including a switching device capable of switching the automatic selection of the sound spectrum on and off.

12. The audio signal processing system of claim 2, further including at least one memory in which a plurality of sound spectra are stored.

13. The audio signal processing system of claim 12, where the sound spectra stored in memory are each mapped to a different type of input audio signal.

14. The audio signal processing system of claim 12, further including means for adding, deleting, and modifying the sound spectra accessed by the sound spectrum selection module.

15. A method for processing an audio input signal with a sound spectrum, the method comprising:
receiving the input audio signal from an audio signal source;
receiving additional information from the audio signal source that is associated with the input audio signal;
selecting the sound spectrum from a plurality of sound spectra responsive to the additional information;
processing the input audio signal with the selected sound spectrum; and
producing an output audio signal from the processed input audio signal.

16. The method of claim 15, where the sound spectrum is automatically selected from the plurality of sound spectra responsive to the additional information.

17. The method of claim 15, where the additional information is transmitted together with the input audio signal and includes program codes or program type codes.

18. The method of claim 15, where the additional information is transmitted independently of the input audio signal.

19. The method of claim 15, where the additional information is obtained from an audio analysis of the input audio signal.

20. The method of claim 19, where the audio analysis of the input audio signal includes a frequency or a dynamic analysis.

21. The method of claim 15, where the additional information used to select the sound spectrum includes an identification of the channel by which the input audio signal is received.
